(19) United States
(12) Patent Application Publication
(10) Pub. No.: US 2025/0391732 A1
(43) Pub. Date: Dec. 25, 2025

(54) SEMICONDUCTOR DEVICE INCLUDING AN INTEGRATED TIM-ON-DIE

(71) Applicant: SanDisk Technologies, Inc., Milpitas, CA (US)

(72) Inventors: Shaopeng Dong, Shanghai (CN); Shrikar Bhagath, San Jose, CA (US); Derek Mong, Penang (MY); Fen Yu, Shanghai (CN); Paul Qu, Shanghai (CN); Jiun Dong Loeh, Penang (MY); Jerry Tang, Shanghai (CN); Zengyu Zhou, Shanghai (CN); Yuanheng Zhang, Shanghai (CN); Rui Guo, Shanghai (CN)

(73) Assignee: SanDisk Technologies, Inc., Milpitas, CA (US)

(21) Appl. No.: 18/748,383

(22) Filed: Jun. 20, 2024

(51) Int. Cl. H01L 23/373; H01L 23/00; H01L 23/31; H01L 23/498; H01L 25/065; H10B 80/00

(52) U.S. Cl. CPC H01L 23/3735; H01L 23/3157; H01L 23/49822; H01L 24/16; H01L 24/97; H01L 23/49816; H01L 25/0655; H01L 2224/16227; H10B 80/00

(57) ABSTRACT

A semiconductor controller includes a controller semiconductor die having an integrated thermal interface material layer, or TIM formed on top of the die. In embodiments, the controller semiconductor die may be mounted on a substrate, for example in a flip-chip configuration. Thereafter, the TIM may be positioned on an upper surface of the controller semiconductor die and the TIM and controller semiconductor die may be positioned within a mold chase for encapsulation in mold compound. After encapsulation, the TIM may be exposed in an upper surface of the encapsulated controller semiconductor die.

### BACKGROUND

The strong growth in demand for portable consumer electronics is driving the need for high-capacity storage devices. Non-volatile semiconductor memory devices are widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computers, cellular telephones and SSD (solid state drives).

While many varied packaging configurations are known, flash memory semiconductor packages may in general be assembled as system-in-a-package (SIP), where a controller die and a number of memory dies are mounted and interconnected to an upper surface of substrate such as a printed circuit board. The package may then be encased in a mold compound.

Current controller dies generate heat which needs to be conducted away from dies. Moreover, there are next generation graphics processing units and AI processing units which work at high speeds and generate a significant amount of heat. It is known to mount a heat sink on top of the mold compound to draw heat away from the controller. However, such heat conduction schemes add height to the overall controller, and are also not very effective at removing heat from the controller.

### DESCRIPTION OF THE DRAWINGS

FIG. 1 is a flowchart of the overall fabrication process of a semiconductor controller according to embodiments of the present invention.

FIG. 2 is a top view of a panel of substrates on which the semiconductor controllers of the present technology may be constructed.

FIG. 3 is a top view of a substrate used in the assembly of a semiconductor controller according to an embodiment of the present technology.

FIG. 4 is a side cross-sectional view of a substrate used in the assembly of a semiconductor controller according to an embodiment of the present technology.

FIG. 5 is a top view of a substrate and controller semiconductor die according to an embodiment of the present technology.

FIG. 6 is a side cross-sectional view of a substrate and controller semiconductor die according to an embodiment of the present technology.

FIG. 7 is a side cross-sectional view of a substrate, controller semiconductor die and TIM layer according to an embodiment of the present technology.

FIG. 8 is a side cross-sectional view of a panel of substrates, controller semiconductor dies and a sheet of TIM layer according to an embodiment of the present technology.

FIG. 9 is an enlarged cross-sectional view of a portion of the TIM layer according to an embodiment of the present technology.

FIG. 10 is a side view of a mold chase for encapsulating a panel of semiconductor controllers according to embodiments of the present technology.

FIG. 11 is a side cross-sectional view of a completed semiconductor controller according to an embodiment of the present technology.

FIG. 12 is a perspective view of a completed semiconductor controller according to an embodiment of the present technology.

FIG. 13 is a side cross-sectional view of a completed semiconductor controller according to an alternative embodiment of the present technology.

FIG. 14 is a perspective view of a completed semiconductor controller according to an alternative embodiment of the present technology.

FIG. 15 is a side cross-sectional view of a completed semiconductor device including a semiconductor controller and memory dies according to an alternative embodiment of the present technology.

### DETAILED DESCRIPTION

The present technology will now be described with reference to the drawings, which in embodiments, relate to a semiconductor controller including a controller semiconductor die having an integrated thermal interface material layer, or TIM formed on top of the die. In embodiments, the controller semiconductor die may be mounted on a substrate, for example in a flip-chip configuration. Thereafter, the TIM may be positioned on an upper surface of the controller semiconductor die and the TIM and controller semiconductor die may be positioned within a mold chase for encapsulation in mold compound. After encapsulation, the TIM may be exposed in an upper surface of the encapsulated controller semiconductor die.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

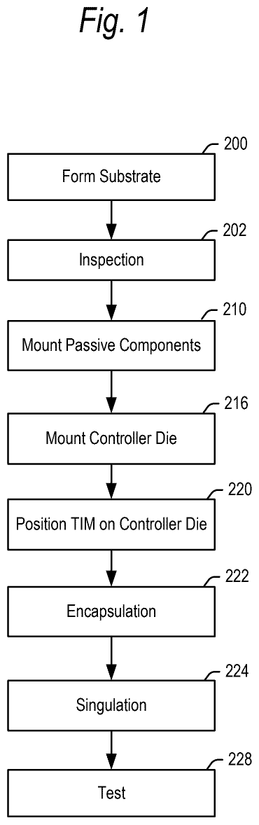

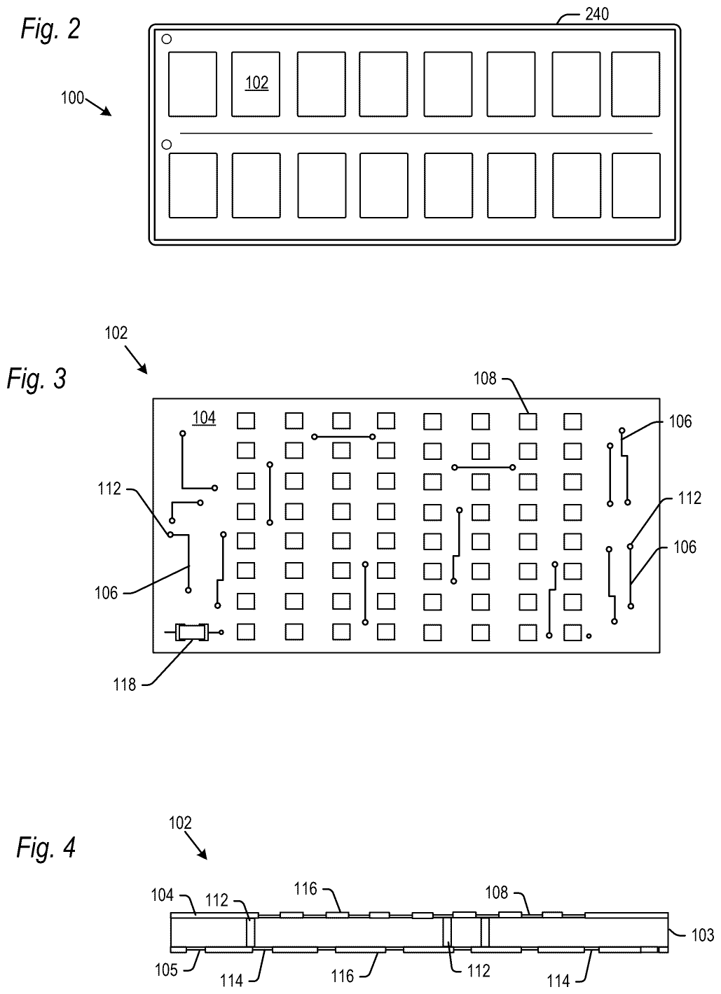

An embodiment of the present invention will now be explained with reference to the flowchart of FIG. 1 and the top, edge and perspective views of FIGS. 2 through 15. As indicated in the top view of FIG. 2, the individual controller dies may be formed on a substrate panel 100 including a number of substrates 102 for economies of scale. The particular number and arrangement of substrate 102 on panel 100 is shown by way of example only, and may vary in further embodiments.

The substrate 102 may be formed in step 200 as shown in the top and edge views of FIGS. 3 and 4, respectively. The substrate panel begins with a plurality of substrates 102 (one such substrate is shown in FIGS. 3 and 4). The substrate 102 may be a variety of different chip carrier mediums for transmitting signals between semiconductor dies on the substrate and a host device. Such chip carrier mediums may include a printed circuit board (PCB), a leadframe or a tape automated bonded (TAB) tape. Where substrate 102 is a PCB, the substrate may be formed of a core 103 having a top conductive layer 104 and a bottom conductive layer 105 as indicated in FIGS. 3 and 4. It is understood that the substrate may have more conductive layers, each separated by a dielectric core layer. The core 103 may be formed of various dielectric materials such as for example, polyimide laminates, epoxy resins including FR4 and FR5, bismaleimide triazine (BT), and the like. The conductive layers 104, 105 may be formed of copper or copper alloys, plated copper or plated copper alloys, Alloy 42 (42Fe/58Ni), copper plated steel, or other metals and materials known for use on substrate panels.

Conductance patterns are formed in one or both of the top and bottom conductive layers 104, 105. The conductance pattern(s) may include electrical traces 106 and contact pads 108 as shown for example in FIGS. 2 and 3. The traces 106 and contact pads 108 (only some of which are numbered in the figures) are by way of example, and the substrate 102 may include more traces and/or contact pads than is shown in the figures, and they may be in different locations than is shown in the figures. The substrate 102 may be drilled to define a number of through-hole vias 112 in the substrate 102. The vias 112 (only some of which are numbered in the figures) are by way of example, and the substrate 102 may include more vias 112 than are shown in the figures, and they may be in different locations than are shown in the figures.

The upper conductance pattern 104 of the substrate 102 may be etched to include contact pads 108 for receiving solder balls as explained below. The lower conductance pattern 105 of the substrate 102 may also be etched to include contact pads 114 for receiving solder balls as explained below. The conductance patterns on the top and/or bottom surfaces of the substrate 102 may be formed by a variety of known processes, including for example various photolithographic processes. A solder mask 116 may be applied over the conductance patterns in the top and bottom surfaces, leaving the various contact pads 108, 114 exposed.

The substrate 102 may next be inspected and tested in step 202 to check electrical operation, and for contamination, scratches and discoloration. Assuming the substrate 102 passes inspection, passive components 118 (FIG. 3) may next be affixed to the substrate in a step 210. The one or more passive components may include for example one or more capacitors, resistors and/or inductors, though other components are contemplated. The passive component 118 shown is by way of example only, and the number, type and position may vary in further embodiments.

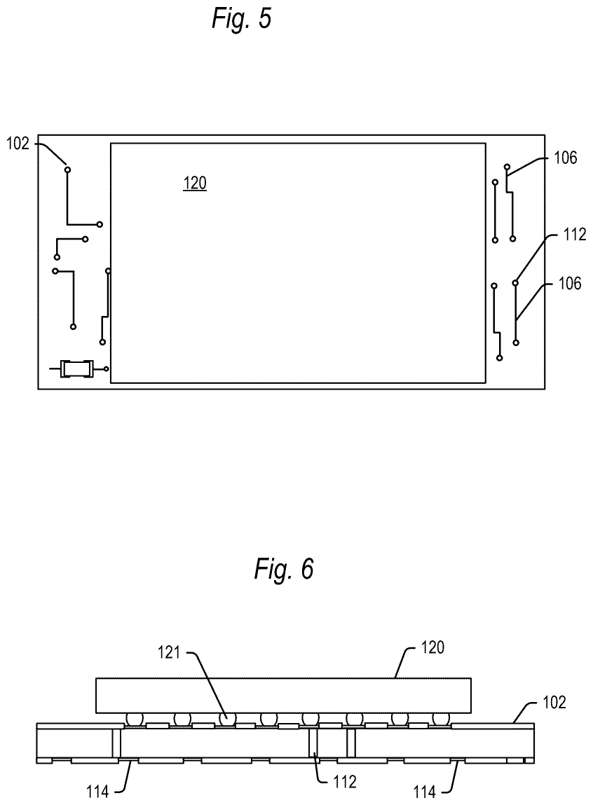

A controller semiconductor die 120 may next be mounted on the substrate 102 in step 216 and as shown in the top and edge views of FIGS. 5 and 6, respectively. The controller semiconductor die 120 may for example be traditional ASIC controller for controlling the operation of other semiconductor dies, such as for example the semiconductor memory dies shown in FIG. 15 and described below. In further embodiments, the controller die 120 may be a specialized controller, including for example a graphics processing unit or an artificial intelligence (AI) processing unit. The controller die 120 may be other types of controllers in further embodiments. The controller die 120 may be mounted to the substrate 102 in a flip-chip configuration, using solder balls 121. The solder balls 121 may be affixed to bond pads (not shown) on the controller die 120, and onto contact pads 108 on the substrate. Once connected, the solder balls 121 may be reflowed to physically and electrically couple the controller die 120 to the substrate 102.

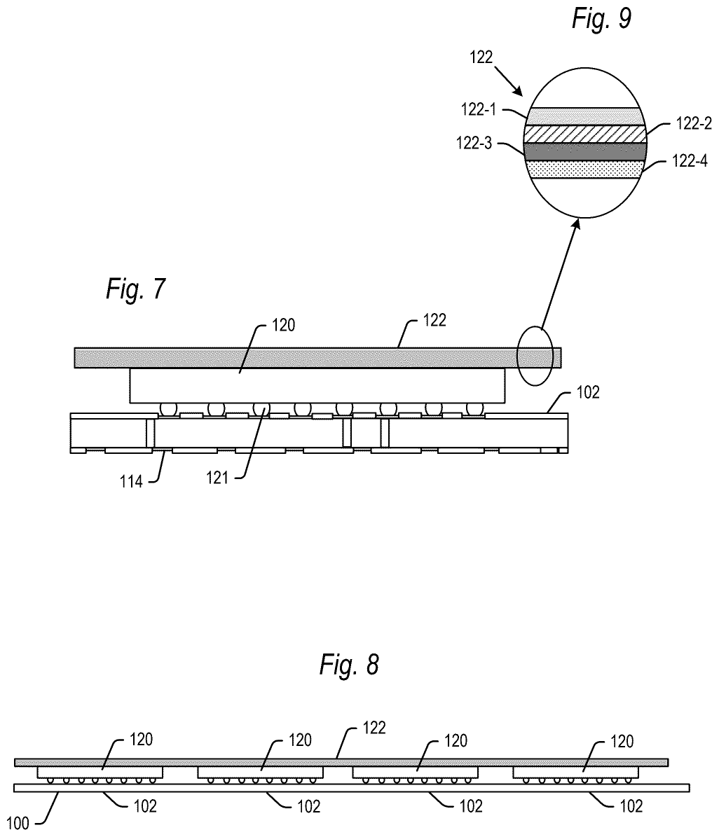

Following mounting of the controller die 120, a thermal interface material (TIM) layer 122 may be positioned on top of the controller die 120 in step 220 as shown in FIG. 7. As indicated in FIG. 8, the TIM layer 122 may be positioned as a sheet over all of the substrates 102 and controller dies 120 in the panel 100. As indicated in the enlarged sectional view of FIG. 9, the TIM layer 122 may in fact be comprised of a number of sublayers, including for example layers 122-1, 122-2, 122-3 and 122-4, where the layers together are provided to optimize the heat transfer capability of the TIM layer 122. In one example, the first (top) sublayer 122-1 may be Chromium, the second sublayer 122-2 may be Nickel, the third sublayer 122-3 may be Copper and the fourth sublayer 122-4 may be a an adhesive interface or a solder mask material. The adhesive/solder mask sublayer can be made up of epoxy or polymer material blended with fillers such as ceramic or metal oxide (i.e., silicon dioxide, aluminum oxide, aluminum nitride, etc.), and/or carbon nanotubes/nanofibers or graphene for higher heat dissipation. The sublayers 122-1 through 122-3 may optimize the heat transfer capabilities of the TIM layer 122 and the sublayer 122-4 may be provide to adhere the TIM layer 122 to the controller die 120.

In one example, the thickness of the first sublayer 122-1 may range from 1 to 5 microns (μm), the second sublayer 122-2 may range from 5-10 μm, the third sublayer 122-3 may range from 90 to 130 μm and the fourth sublayer 122-4 may range from 10-30 μm. The overall thickness of the TIM layer 122 may range from 100 μm to 150 μm. It is understood that these thicknesses are by way of example only and each sublayer may be thinner or thicker than this range in further embodiments. In one such further embodiment, the overall thickness of the metal sublayers (Cu/Ni/Cr) may range from 5 μm to 300 μm and the adhesive/solder mask sublayer may range from 5 μm to 100 μm.

It is also understood that the number of sublayers may be more or less than four, and that the composition of each sublayer may be different than that set forth above. In one further embodiment, the TIM layer 122 may be comprised of two sublayers-one of Copper and a second of an adhesive interface or solder mask material. Other materials may be included in TIM layer 122 instead of, or in addition to, one or more of those materials set forth above, including for example Aluminum, Copper Alloys such as copper-tungsten (Cu—W) or copper-molybdenum (Cu—Mo), Aluminum Alloys such as aluminum-silicon (Al—Si), alloys of Copper and Aluminum, and graphite.

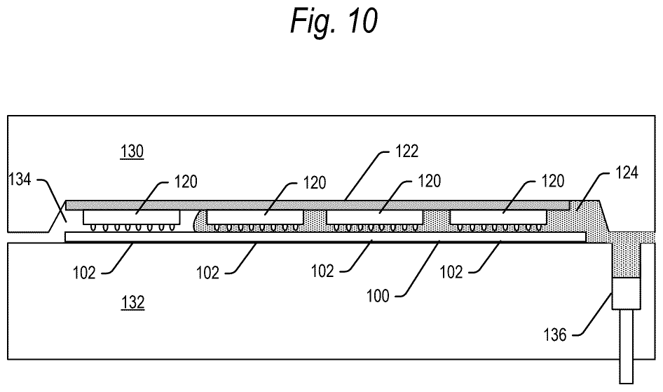

After the TIM layer 122 is positioned on the controller die 120, the controller die 120 and TIM layer 122 may be encapsulated in an encapsulant such as mold compound 124 in step 222 and as shown in FIG. 10. The encapsulation step 222 may be performed by positioning the panel 100 including substrates 102, controller dies 120 and TIM layer 122 between top and bottom mold plates 130, 132. With the top and bottom mold plates 130, 132 pressed together, liquid mold compound may be injected into a cavity 134 between the mold plates from an injection system 136. FIG. 10 illustrates the mold compound encapsulating some of the controller dies 120 and moving toward the remaining controller dies 120.

Mold compound 124 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other encapsulants from other manufacturers are contemplated. While FIG. 10 illustrates one particular encapsulation process, other encapsulation processes may be used, including for example FFT (Flow Free Thin) compression molding, in further embodiments.

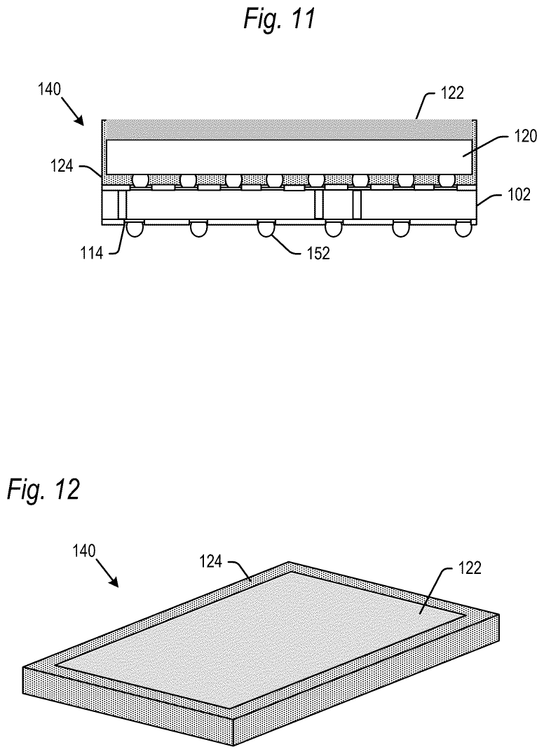

The respective controllers may be singulated in step 224 from the panel 100 to form the finished semiconductor controller 140 as shown in FIGS. 11 and 12. Each controller 140 may be singulated by any of a variety of cutting methods including sawing, water jet cutting, laser cutting, water guided laser cutting, dry media cutting, and diamond coating wire cutting. While straight line cuts will define generally rectangular or square shaped controller 140, it is understood that controller 140 may have shapes other than rectangular and square in further embodiments of the present invention. Once cut into individual controllers 140, the controllers may be tested in a step 228 to ensure the devices are functioning properly.

Given the positioning of the TIM layer 122 on the controller dies 120 and during the encapsulation step 222, it is a feature of the present technology that the TIM layer 122 has a first surface which lies in contact with the controller die 120 and a second, opposed surface which is exposed on an upper surface of the finished controller 140. This feature provides a low profile controller with excellent heat conduction away from the control die 120.

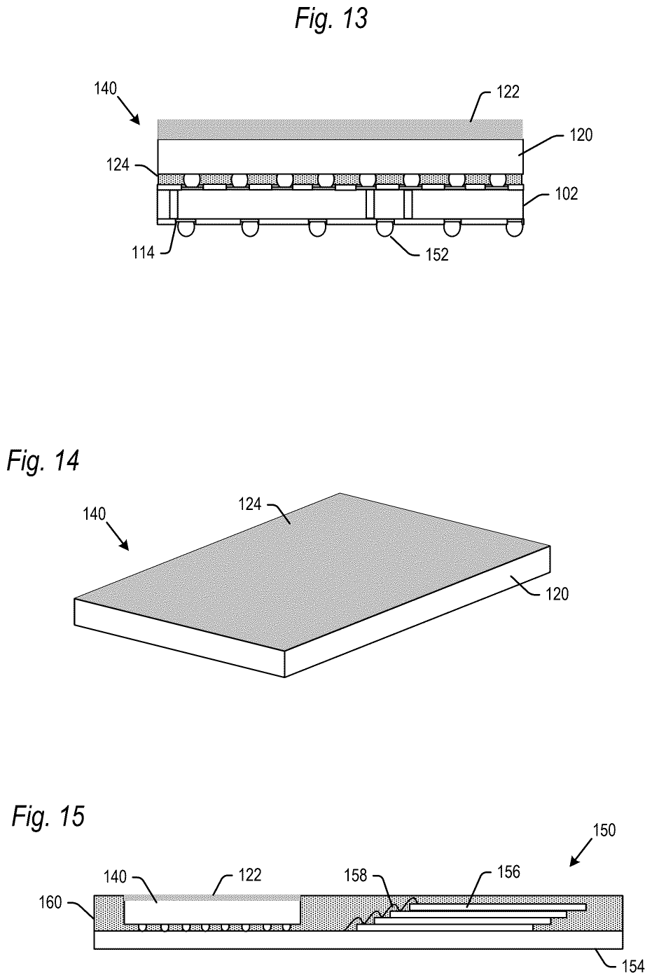

As shown in FIGS. 11 and 12, the controllers 140 may be singulated from the panel 100 so that the mold compound 124 forms a border around the sides of the controller die 120 and the TIM layer 122 at a top surface of the controller 140. However, in further embodiments shown in FIGS. 13 and 14, the controllers 140 may be singulated from the panel 100 so that the TIM layer 122 forms the entire upper surface of the semiconductor controller; that is, there is no mold compound border around the TIM layer 122 at a top surface of the controller 140. The top surface in this embodiment is solely the exposed TIM layer 122.

The finished controller 140 may be used in a variety of semiconductor packages, including a memory package 150 as shown in FIG. 15. Solder balls 152 (FIGS. 11 and 13) may be mounted to the contact pads 114 on a bottom surface of substrate 102. The solder balls allow the controller to be physically and electrically coupled to a further substrate or PCB, for example substrate 154 of memory package 150 shown in FIG. 15. Memory package 150 may further include a plurality of semiconductor memory dies 156, including for example nonvolatile memories, such as 3D BiCS (Bit Cost Scaling) and V-NAND. Other types of memory dies may alternatively or additionally be used including volatile memories such as DRAM and SRAM. The number of memory dies 156 shown is by way of example only and there may be more or less memory dies in further embodiments. The memory dies may be electrically coupled to each other and the substrate 154 for example by bond wires 158.

The package 150 may be encapsulated in a mold compound 160. In embodiments, the TIM layer 122 of controller 140 may be exposed through an upper surface of the mold compound 160 in the memory package 150. This provides efficient heat conduction away from the controller 140 when used in package 150.

In summary, in one example, the present technology relates to a semiconductor controller, comprising: a substrate; a controller semiconductor die physically and electrically mounted to the substrate; a thermal interface material (TIM) layer comprising first and second opposed surfaces, the first surface of the TIM layer affixed to a surface of the controller semiconductor die, the TIM layer configured to conduct heat away from the controller semiconductor die; and an encapsulant for at least partially encapsulating the semiconductor controller, wherein the second surface of the TIM layer is exposed through the encapsulant.

In another example, the present technology relates to a semiconductor memory package, comprising: a first substrate; one or more semiconductor memory dies physically and electrically coupled to the first substrate; and a semiconductor controller for controlling operation of the one or more semiconductor memory dies, the semiconductor controller comprising: a second substrate; a controller semiconductor die physically and electrically mounted to the second substrate; a thermal interface material (TIM) layer comprising first and second opposed surfaces, the first surface of the TIM layer affixed to a surface of the controller semiconductor die, the TIM layer configured to conduct heat away from the controller semiconductor die; and an encapsulant for at least partially encapsulating the semiconductor controller, wherein the second surface of the TIM layer is exposed through the encapsulant.

In a further example, the present technology relates to a semiconductor controller, comprising: a substrate; a controller semiconductor die physically and electrically mounted to the substrate; thermal interface means, connected to the controller semiconductor die, for conducting heat away from the controller semiconductor die; and an encapsulant for at least partially encapsulating the semiconductor controller, wherein a portion of the thermal interface means is exposed through the encapsulant.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor controller, comprising:
a substrate;
a controller semiconductor die physically and electrically mounted to the substrate;
a thermal interface material (TIM) layer comprising first and second opposed surfaces, the first surface of the TIM layer affixed to a surface of the controller semiconductor die, the TIM layer configured to conduct heat away from the controller semiconductor die; and
an encapsulant for at least partially encapsulating the semiconductor controller, wherein the second surface of the TIM layer is exposed through the encapsulant.

2. The semiconductor controller of claim 1, wherein the controller semiconductor die is flip-chip mounted to the substrate by a plurality of solder balls.

3. The semiconductor controller of claim 1, wherein the TIM layer is comprised of a plurality of sublayers.

4. The semiconductor controller of claim 3, wherein a first sublayer of the TIM layer is comprised of Copper.

5. The semiconductor controller of claim 4, wherein a second sublayer of the TIM layer is comprised of one of a thermally conductive adhesive and a thermally conductive solder mask.

6. The semiconductor controller of claim 5, wherein a third sublayer of the TIM layer is comprised of Nickel and a fourth sublayer of the TIM layer is comprised of Chromium.

7. The semiconductor controller of claim 1, wherein the encapsulant is applied to the controller semiconductor die after the TIM layer is affixed to the controller semiconductor die.

8. The semiconductor controller of claim 1, wherein the encapsulant forms a border around at least one side of the exposed second surface of the TIM layer.

9. The semiconductor controller of claim 1, wherein the exposed second surface of the TIM layer forms the entire upper surface of the semiconductor controller.

10. The semiconductor controller of claim 1, wherein the encapsulant is mold compound applied using a pair of mold plates.

11. The semiconductor controller of claim 1, wherein the semiconductor controller is one of a plurality of semiconductor controllers formed on a panel, wherein the TIM layer is applied as a sheet over all of the plurality of semiconductor controllers on the panel.

12. The semiconductor controller of claim 1, wherein the TIM layer is singulated from the panel with the controller semiconductor die.

13. The semiconductor controller of claim 1, wherein the semiconductor controller is an ASIC.

14. The semiconductor controller of claim 1, wherein the semiconductor controller is a specialized processor comprising one of a graphics processing unit and an artificial intelligence processing unit.

15. A semiconductor memory package, comprising:
a first substrate;
one or more semiconductor memory dies physically and electrically coupled to the first substrate; and
a semiconductor controller for controlling operation of the one or more semiconductor memory dies, the semiconductor controller comprising:
a second substrate;
a controller semiconductor die physically and electrically mounted to the second substrate;
a thermal interface material (TIM) layer comprising first and second opposed surfaces, the first surface of the TIM layer affixed to a surface of the controller semiconductor die, the TIM layer configured to conduct heat away from the controller semiconductor die; and
an encapsulant for at least partially encapsulating the semiconductor controller, wherein the second surface of the TIM layer is exposed through the encapsulant.

16. The semiconductor memory package of claim 15, wherein the encapsulant comprises a first encapsulant, the semiconductor memory package further comprising a second encapsulant around the controller semiconductor die and the one or more memory dies, wherein the second surface of the TIM layer is exposed through the second encapsulant.

17. The semiconductor memory package of claim 15, wherein the TIM layer is comprised of a plurality of sublayers of different materials.

18. The semiconductor controller of claim 15, wherein the encapsulant is applied to the controller semiconductor die after the TIM layer is directly affixed to the controller semiconductor die.

19. The semiconductor controller of claim 15, wherein the encapsulant forms a border around at least one side of the exposed second surface of the TIM layer.

20. A semiconductor controller, comprising:
a substrate;
a controller semiconductor die physically and electrically mounted to the substrate;
thermal interface means, connected to the controller semiconductor die, for conducting heat away from the controller semiconductor die; and
an encapsulant for at least partially encapsulating the semiconductor controller, wherein a portion of the thermal interface means is exposed through the encapsulant.
